(19) United States
(12) Patent Application Publication
(10) Pub. No.: US 2006/0286705 A1
(43) Pub. Date: Dec. 21, 2006

(54) Method of passivating compound semiconductor surfaces

(75) Inventors: James Hyland, Hamden, CT (US); Eric S. Harmon, Norfolk, MA (US); David B. Salzman, Chevy Chase, MD (US); Robert D. Koudelka, Albuquerque, NM (US); Jerry M. Woodall, West Point, IN (US)

Correspondence Address: David Garrod, Ph.D., Esq.;Goodwin Procter LLP, 599 Lexington Avenue, New York, NY, 20022, US

(73) Assignee: Yale University, New Haven, CT (US)

(21) Appl. No.: 11/358,606

(22) Filed: Feb. 21, 2006

Related U.S. Application Data
(60) Provisional application No. 60/655,585, filed on Feb. 21, 2005.

(51) Int. Cl. H01L 21/00

(52) U.S. Cl. 438/38

(57) ABSTRACT

The invention discloses a method of passivating compound semiconductor surfaces aligned to the {110} crystal planes, and devices incorporating said passivated surfaces.

The U.S. Government may have an interest in this patent arising from contracts F30602-03-C-0211 or W31P4Q-04-C-R309.

### FIELD OF THE INVENTION

This invention relates generally to the field of creating compound semiconductor materials and semiconductor devices, and more particularly to the passivation of the surfaces of semiconductor devices, including diode, avalanche photodiodes (APDs), laser diodes, transistors, bipolar junction transistors (BJTs), heterojunction bipolar junction transistors (HBTs), and field effect transistors (FETs). It applies especially to diodes and transistor devices fabricated from III-V compound semiconductors.

### BACKGROUND OF THE INVENTION AND LIMITATIONS OF THE PRIOR ART

It is well-known that microelectronic devices (e.g. diode structures including avalanche photodiodes (APDs), laser diodes, and heterojunction bipolar junctions) formed from III-V compound semiconductors exhibit excessive surface recombination of charge carriers at mesa side-walls. (P E Dodd, T B Stellwag, M R Melloch, and M S Lundstrom, “Surface and Perimeter Recombination in GaAs Diodes: An Experimental and Theoretical Investigation,” IEEE Trans. Electron Devices., 38, p. 1253-1261 (1991); A C Irvind and R C Woods, “Recombination current in GaAs/AlGaAs heterostructure bipolar transistors,” Int. J. Electronics, 83(6), pp. 761-777 (1997)). It is also well known that surface and perimeter currents are dependent on orientation and geometry of the device (T B Stellwag, M R Melloch, M S Lundstrom, M S Carpenter, and R F Pierret, “Orientation-dependent perimeter recombination in GaAs diodes,” Appl. Phys. Lett., 56(17), pp. 1658-1660, 23 Apr. 1990), notably in III-V compound semiconductors combining elements of In, Ga, Al, As, P, Sb, and N.

Passivating a surface means to set or alter the surface chemistry in order reduce to the density of surface states and mid gap trap states near the surface, reduce the fixed charge density near a surface, or reduce the trap density near a surface. Passivation of surfaces can be used to reduce surface recombination rates, reduce surface generation rates, and to upin the quasi-Fermi level at and near that surface. Furthermore, improved passivation allows additional trade-offs in optimizing devices.

Mesas are commonly used to expose distinct levels of a microelectronic device in order to contact them electrically, and to isolate adjacent devices electrically or optically. Passivating the side-walls of mesas is critical to high performance for microelectronic devices including photodiodes and bipolar transistors. Other surfaces may likewise be passivated in accordance with the invention, passivating mesa side-walls being the preferred embodiment. A number of techniques have consequently been pursued in attempts to improve passivation of the surface of devices formed in III-V compound semiconductors, including ammonium sulfide (J-Y Kim, J Lee, J Kim, B Kang, and O Kown, “Effect of surface treatment on leakage current of GaAs/AlGaAs laser microcavities,” Appl. Phys. Lett., 82(25), pp. 4504-4506 (23 Jun. 2003)), hydrogen passivation (J Y Lee, Y H Kown, M D Kim, H J Kim, T W Kang, C Y Hong, and H Y Cho, “Enhancement of a rectifying characteristics of InGaP diodes by hydrogenation,” J. Applied Phys., 85(1), pp. 600-603 (1 Jan. 1999)), and numerous others (S Ingrey, “III-V surface processing,” J. Vac. Sci. Technol. A. v. 10(4), pp. 829-836 (July/August 1992)). While many of these approaches have achieved limited passivation of surface states, thereby lowering perimeter leakage currents, better combinations of passivation, long lifetime, and device structure need to be implemented simultaneously to make microelectronic devices more useful.

Passivation is also used to reduce the interface trap denisty and interface charge density at semiconductor-insulator interfaces. This makes passivation useful for field effect devices, including metal-insulator-semiconductor (MIS) devices such as MIS capacitors and MIS guard rings, metal-insulator-semiconductor field effect transistors (MISFETs), metal-insulator-semiconductor heterostructure field effect transistors (MISHFETs), and other field effect transistor (FET) devices.

### OBJECT OF THE INVENTION

Primary objects of the invention include a means for passivating surfaces of microelectronic devices formed from compound semiconductors, including mesa sidewall surfaces, top surfaces, and other surfaces of a device. Other objects of the invention include a means for creating mesa and other device structures with surfaces compatible with the passivation methods, and methods of treating compound semiconductor surfaces to passivate surface states.

### BRIEF DESCRIPTION OF THE DRAWINGS

FIG. 1A shows the layer structure of the diode structure used in the preferred embodiment of the invention.

FIG. 1B shows an overhead view of the geometry of prior art round devices fabricated from the layer structure of FIG. 1A.

FIG. 1C shows an overhead view of the geometry of rectangular devices fabricated from the layer structure of FIG. 1A in accordance with the preferred embodiment of the invention.

FIG. 1D shows a cross sectional view of the geometry of rectangular devices fabricated from the layer structure of FIG. 1A in accordance with the preferred embodiment of the invention.

FIG. 1E shows the current-voltage characteristics of prior art and preferred embodiment diodes fabricated from the layer structure of FIG. 1A.

FIG. 2A shows the layer structure of the alternative embodiment.

FIG. 2B shows the current-voltage characteristics diodes fabricated in accordance with the prior art and in accordance with the invention from the layer structure of FIG. 2A.

### BRIEF SUMMARY OF THE INVENTION

We disclose herein a novel means of passivating the mesa side-walls of certain microelectronic device structures. The method is stable, and enables the reverse-bias dark-current to be lowered greatly (by a factor of at least 10) compared to similar devices that do not use the passivation. Furthermore, the reverse bias dark current in these devices becomes markedly less dependent on bias voltage. The invention entails the following steps:
1. Confine the active surfaces of the device such that each side-wall is predominately aligned to one of the {110} planes (including <011>, <01-1>, <0-1-1>, <0-11>). This confinement can be achieved by etching using a mask whose edges are aligned to a {110} plane, cleaving along said {110} planes, or forming devices on the surface of a {110} oriented wafer. Ideally, the etching approach provides smooth facets aligned solely to the {110} planes, but non-ideal etchants with sloped side-walls incorporating multiple crystal planes have been proven to work as well.
2. Optionally, remove surface layers such as surface oxides. This can be achieved by applying a NH₄OH etching solution (including NH₄OH+H₂O+H₂O₂, NH₄OH+H₂O, and undiluted NH₄OH) to the surface to be passivated. Alternative means of removing remove surface layers include etching in sulfuric acid solutions, phosphoric acid solutions, acetic acid solutions, Br:methanol solutions, distilled water (H₂O) and photo-etching (e.g. S D Offsey, J M Woodall, A C Warren, P D Krichner, T I Chappell, and G D Pettit, “Unpinned (100) GaAs surfaces in air using photochemistry,” Appl. Phys. Lett. 48(7), pp. 475-477 (17 Feb. 1986)). These etchants may also be useful to remove the semiconductor region damaged by dry etching approaches such as reactive ion etching (RIE), which is known to produce damage in III-V semiconductors.
3. Passivate the active surfaces of the device by submerging said surfaces in a solution of HF, including solutions of buffered oxide etch (BOE), and solutions diluted by H₂O or other solvents.

4. Complete the fabrication of the device, which generally includes encapsulation of the devices in a dielectric such as SiO₂. Note that in the preferred embodiment, the device is a rectangular mesa APD, with each of the edges of the rectangular mesa approximately aligned to a {110} plane. Alternative embodiments include rectangular diodes for switching or rectification applications, edge-emitting laser diode structures, and transistor structures such as HBTs and FETs, provided such structures include active surfaces aligned to {110} planes.

The invention requires two key components: using devices where active surfaces of the device aligned approximately parallel to the {110} crystal planes, and submerging said surfaces in a HF solution as the last of the wet chemical etching steps. We note here that while the preferred embodiment incorporates rectangular mesas that are approximately aligned to {110} planes, said mesa side-walls are etched with standard chemical etching procedures, so can exhibit sloped side-walls, exposing multiple crystal planes along the perimeter. In general, mesas whose side-walls all align to {110} planes will exhibit superior passivation to those with more use of other crystal planes.

### DETAILED DESCRIPTION OF THE FIGURES

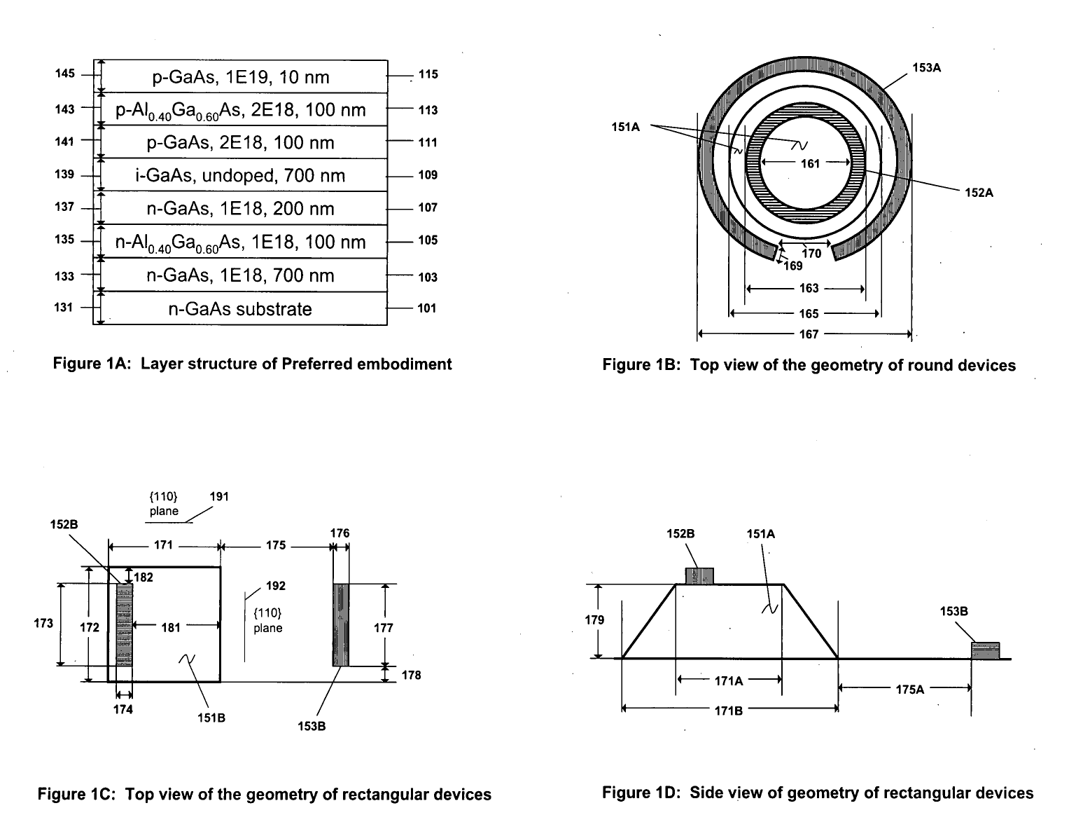

Reference is now made to FIG. 1A, showing the layer structure used in the preferred embodiment of the invention. The structure is grown on a (100) n-type GaAs substrate 101 of thickness 131 using metal-organic chemical vapor deposition (MOCVD). On top of layer 101 is grown layer 103 of n-type GaAs doped with a silicon to doping density of 1×10¹⁸ cm⁻³. The thickness 133 of layer 103 is 700 nm. On top of layer 103 is grown layer 105 consisting of n-type Al_{0.40}Ga_{0.60}As doped with silicon to a doping density of 1×10¹⁸ cm⁻³. The thickness 135 of layer 105 is 100 nm. On top of layer 105 is grown layer 107 consisting of an n-type GaAs doped with silicon to a doping density of 1×10¹⁸ cm⁻³. The thickness 137 of layer 107 is 200 nm. On top of layer 107 is grown layer 109 consisting of undoped GaAs grown to a thickness 139 of 700 nm. On top of layer 109 is grown layer 111, consisting of p-type GaAs doped with Zn to a doping density of 2×10¹⁸ cm⁻³. The thickness 141 of layer 111 is 100 nm. On top of layer 111 is grown layer 113, consisting of p-type Al_{0.40}Ga_{0.60}As doped with Zn to a doping density of 2×10¹⁸ cm⁻³. The thickness 143 of layer 113 is 100 nm. On top of layer 113 is grown layer 115, consisting of p-type GaAs doped with Zn to a doping density of 1×10¹⁹ cm⁻³. The thickness 145 of layer 115 is 10 nm.

Reference is now made to FIG. 1B, showing an overhead view (not to scale) of the geometry of prior art mesa isolated round devices fabricated from the layer structure of FIG. 1A. Standard photolithographic techniques were use to define contact 152A, which consists of a metal ring of inner diameter 161 and outer diameter 163, and which makes ohmic contact to the top side of the mesa by making intimate contact to layer 115. Next, standard photolithographic techniques were used to define the round mesa 151A of diameter 165. Wet chemical etching was used to remove all of layer 115, 113, 111, 109, 108, 105, and some of layer 103 from the region outside mesa 151A. Next, standard photolithographic techniques were used to define the n-type contact 153A, with outer diameter 167 and thickness 169 as shown in the figure. Note that contact 153A is not a complete ring, but includes a cutout of length 170 so that a metal interconnect layer could be added which connects to contact 152A but does not cross over contact 153A. Those skilled in the art will recognize that both contacts 152A and 153A should be formed from alloyed contacts in order to achieve low resistance ohmic contacts. Contact 152A was formed using the well known Au:Zn alloyed contact metallization scheme for p-GaAs, while contact 153A was formed using the well known AuGeNi contact metallization scheme for n-GaAs.

Reference is now made to FIG. 1C, showing an overhead view of the geometry (not to scale) of devices fabricated in accordance with the preferred embodiment of the invention from the layer structure of FIG. 1A. Standard photolithographic techniques were use to define contact 152B, which consists of a metal stripe with long dimension 173 and short dimension 174. Contact 152B makes ohmic contact to layer 115 on top of mesa 151B using a standard alloyed contact metallization well known to those skilled in the art. The space between contact 152B and the upper edge of the mesa is 182, and the space between the contact 152B and the right side of the mesa is 181. Next, standard photolithographic techniques were used to define the rectangular mesa 151B of dimensions 171 and 172 as shown in the Figure. Wet chemical etching was used to remove all of layer 115, 113, 111, 109, 108, 105, and some of layer 103 from the region outside mesa 151B. Next, standard photolithographic techniques were used to define the n-type contact 153B, with long dimension 177 and short dimension 176 as shown in the Figure. Contact 153B makes ohmic contact to layer 103 using a standard alloyed contact metallization well known to those skilled in the art. The lateral distance between the edge of mesa 151B and contact 153B is 175, while the spacing between the bottom edge of mesa 151B and contact 153B is 178 as shown in the Figure. In accordance with the invention, the mesa side-walls are approximately aligned parallel to {110} plane 191 and {110} plane 192 as shown in the Figure.

Reference is now made to FIG. 1D, showing a cross sectional view of the geometry (not to scale) of devices fabricated in accordance with the preferred embodiment of the invention from the layer structure of FIG. 1A. As shown in the Figure, wet chemical etching of the mesa side-walls generally results in sloped mesa side-walls, where the top of mesa 151A has a lateral dimension 171A, and the bottom of mesa 151A has a lateral dimension of 171B. The space between the bottom of mesa 151A and contact 153B is 175A. While the cross sectional view of FIG. 1D is parallel to crystal plane 191, those skilled in the art will recognize that cross sectional views in other directions (such as parallel to crystal plane 192) will have similar characteristics). Those skilled in the art will also recognize that, in the case of isotropic etching dimension 171B will be larger than dimension 171A, while in the case of anisotropic etching, dimension 171B could be equal to dimension 171A or even smaller than dimension 171A (see TB Stellwag, MR Melloch, MS Lundstrom, MS Carpenter, and RF Pierret, “Orientation-dependent perimeter recombination in GaAs diodes,” Appl. Phys. Lett., v. 56(17), pp. 1658-1660, 23 Apr. 1990).

Reference is now made to FIG. 1E, showing the current-voltage characteristics of prior art and preferred embodiment diodes fabricated from the layer structure of FIG. 1A. Prior art diodes with round mesa geometry and preferred embodiment diodes with square mesas aligned to the {110} directions were fabricated in a piece of a wafer grown in accordance with the layer structure of FIG. 1A. The mesas were etched using conventional wet chemical etching solutions such as 3 NH₄OH: 1 H₂O₂: 5OH₂O. In accordance with the invention, upon completion of the etching of the mesa structures, the devices were submerged into BOE solution for approximately 1 minute to passivate the side-walls of the mesa. After BOE passivation of the side-walls, the wafers were introduced into a plasma enhanced chemical vapor deposition (PECVD) chamber for the deposition of a SiO₂ dielectric layer, to encapsulate the devices and provide an interlayer dielectric. Axis 198 is the magnitude of the current response, in a log scale running from 10⁻¹² Amps to 10⁻⁴ Amps. Axis 199 is the bias voltage, in a linear scale running between −30 Volts and +5 Volts. Curve 196 shows the current response for a prior art round device with mesa 151A diameter 165 of approximately 60 μm, corresponding to a mesa area of about 2827 μm². Curve 195 shows the current response of a device in accordance with the preferred embodiment. This device is square, with dimensions 171 and 172 both being approximately 50 μm, giving a mesa 151B with an area of approximately 2500 μm². The current-voltage characteristic 195 exhibits almost ideal reverse bias diode characteristics, and exhibits more than two orders of magnitude lower reverse bias leakage current near breakdown when compared with curve 196. Since the mesa area of the prior art and preferred embodiment diodes is similar, and both devices were formed in a single fabrication run on a single wafer, the differences in reverse bias leakage current can only be explained by their different geometries, with the square device exhibiting significantly lower leakage currents. It is well known that the leakage current in GaAs mesa diodes is generally dominated by surface generation, and therefore the preferred embodiment provides a means of passivating surface generation and lowering the diode leakage current.

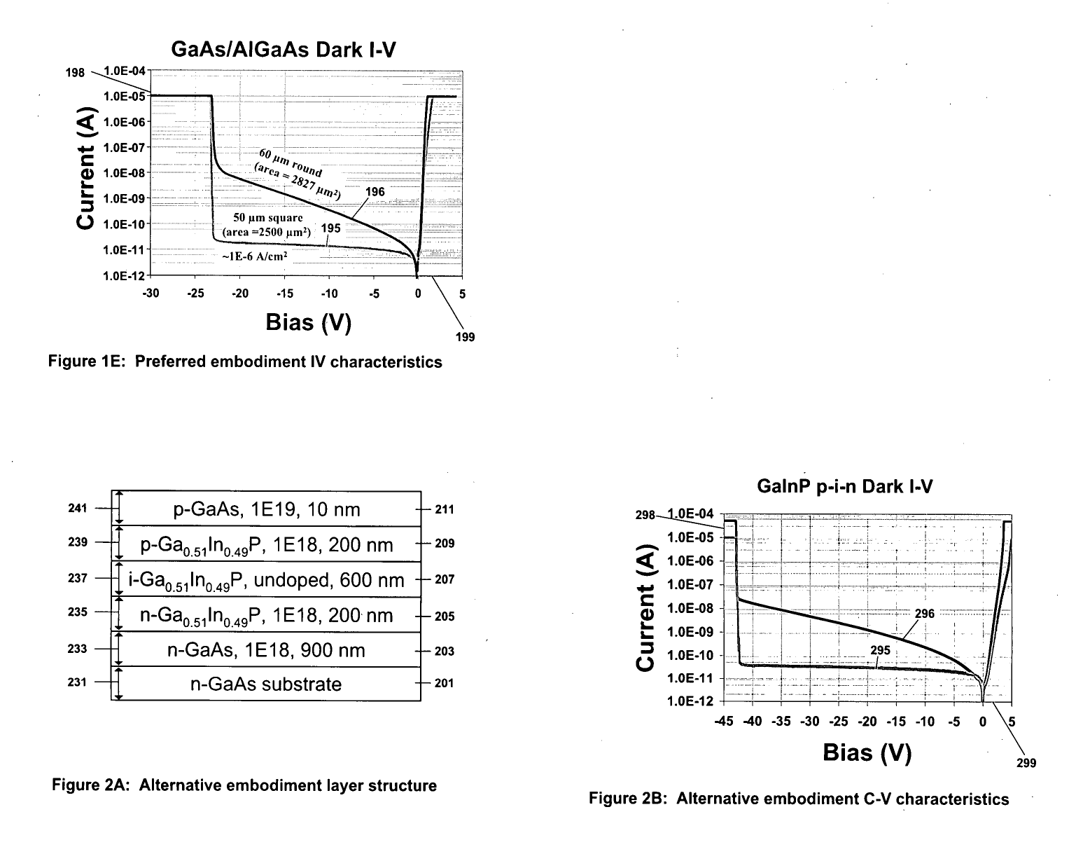

Reference is now made to FIG. 2A shows the layer structure of an alternative embodiment in accordance with the invention, using GaInP in the active region of the device instead of GaAs. The structure is grown on a (100) n-type GaAs substrate 201 of thickness 231 using metal-organic chemical vapor deposition (MOCVD). On top of layer 201 is grown layer 203 of n-type GaAs doped with a silicon to doping density of 1×10¹⁸ cm⁻³. The thickness 233 of layer 203 is 900 nm. On top of layer 203 is grown layer 205 consisting of n-type Ga_{0.51}In_{0.49}P doped with silicon to a doping density of 1×10¹⁸ cm⁻³. The thickness 235 of layer 205 is 200 nm. On top of layer 205 is grown layer 207 consisting of undoped Ga_{0.51}In_{0.49}P grown to a thickness 237 of 600 nm. On top of layer 207 is grown layer 209, consisting of p-type Ga_{0.51}In_{0.49}P doped with Zn to a doping density of 2×10¹⁸ cm⁻³. The thickness 239 of layer 209 is 200 nm. Those skilled in the art will recognize that Ga_{0.51}In_{0.49}P is approximately lattice-matched to GaAs, and therefore high quality, single crystal epilayers of Ga_{0.51}In_{0.49}P may be grown on GaAs substrates with low defect densities. On top of layer 209 is grown layer 211, consisting of p-type GaAs doped with Zn to a doping density of 1×10¹⁹ cm⁻³. The thickness 241 of layer 211 is 10 nm.

Reference is now made to FIG. 2B, showing the current-voltage characteristics of prior art and preferred embodiment diodes fabricated from the layer structure of FIG. 2A. Diodes with round and square mesas were fabricated in a piece of a wafer grown in accordance with the layer structure design presented FIG. 2A. The mesas were etched using bromine methanol wet chemical etching solution. In accordance with the invention, upon completion of the etching of the mesa structures, the devices were submerged into BOE solution for approximately 1 minute to passivate the side-walls of the mesa. After BOE passivation of the side-walls, the wafers were introduced into a plasma enhanced chemical vapor deposition (PECVD) chamber for the deposition of a SiO₂ dielectric layer, to encapsulate the devices and provide an interlayer dielectric. Axis 298 is the magnitude of the current response, in a log scale running from 1E-12 Amps to 1E-4 Amps. Axis 299 is the bias voltage, in a linear scale running between −45 Volts and +5 Volts. Curve 296 shows the current response for a prior art round device with mesa 151A diameter 165 of approximately 60 μm, corresponding to a mesa area of about 2827 μm². Curve 295 shows the current response of a device in accordance with the invention. This device is square, with dimensions 171 and 172 both being approximately 100 μm, giving a mesa 151B with an area of approximately 10,000 μm². The current-voltage characteristic 295 exhibits almost ideal reverse bias diode characteristics, and exhibits about two orders of magnitude lower reverse bias leakage current near breakdown when compared with curve 296. Since the mesa area of the square device fabricated in accordance with the invention is about 3.5 time larger in are than the prior art device, and both devices were formed in a single fabrication run on a single wafer, the differences in reverse bias leakage current can only be explained by their different geometries, with the square device exhibiting significantly lower leakage currents. It is well known that the leakage current in Ga_{0.51}In_{0.49}P mesa diodes is generally dominated by surface generation, and therefore the invention provides a means of passivating surface generation and lowering the diode leakage current.

Other embodiments are anticipated, including embodiments using other III-V compound semiconductors, embodiments using alternative epitaxial growth techniques such as molecular beam epitaxy (MBE) or liquid phase epitaxy (LPE), embodiments using separate absorption, collection, and multiplication, and other APD structures (see. For instance J C Campbell and P Yuan, “Avalanche Photodiodes with an Impact-Ionization-Engineered Multiplication Region,” U.S. Pat. App. No. 2003/0047752 A1, Mar. 13, 2003). Also, note that while the preferred embodiment shows the primary advantage for reverse-biased applications, it is anticipated that forward-biased applications such as the base-emitter junction of an HBT will benefit from improved passivation of mesa side-walls, edges, corners, and surfaces. Thus, it is anticipated that HBTs with the emitter fingers aligned to {110} planes will benefit from submersion in BOE to passivate the mesa side-walls and thereby lower the perimeter current. Such a benefit enables smaller HBT emitter widths to be used, enabling scaling to higher frequency operation.

In addition to bipolar devices, any device incorporating a semiconductor surface in an active region of the device can benefit from the invention. One important class of devices that can benefit from the invention includes MIS devices, where the metal is used to induce a field inside the semiconductor. Such devices are well known to suffer degradation due to surface states, and therefore passivation of said surface states will enhance the MIS performance. One important class of MIS devices are MISFETs and MISHFETs. A MISFET or MISHFET in accordance with the invention would have the semiconductor-insulator interface formed on a {111} semiconductor surface, with said {110} semiconductor surface being dipped in an HF solution immediately prior to deposition of the gate insulator layer.

Devices operated at or near their breakdown voltage in the prior art, such as APDs, do not generally use square or rectangular mesa structures; the use of corners in the present invention is counterintuitive. Indeed, all prior art APDs using III-V semiconductors and conventional mesa isolation (without guard rings) use round devices without any corners, thereby avoiding field crowding in the corners. This is because a rectangular diode structure ordinarily exhibits field crowding at the corners, which increases the magnitude of the electric field there, usually producing premature breakdown in said corners before bulk breakdown, so degrades performance by causing non-uniform avalanche gain, and lowers yield by exacerbating device-to-device variation in breakdown voltage. Mesa devices often exhibit field crowding along edges' too (see chapter 3 of B Jayant Baliga, Power Semiconductor Devices, PWS Publishing Company, Boston, 1996). Square devices have been used for silicon APDs where processing tricks such as beveled edges are used to lower the electric field at mesa side-walls, and dopant diffusion processes are used, which naturally result in rounding of the electric field near corners. The invention prevents premature breakdown at the corner by combining the following three effects:

Rounded corners. Rounded corners may be used to provide a small amount of curvature at the corners, reducing the field crowding. Note, however, that the surface passivation effect requires mesa side-walls consisting of primarily {110} planes, and rounded corners will incorporate other crystal planes. To reduce perimeter currents, it is desirable to use as small a radius of curvature as is practical at the corners, provided it does not cause premature breakdown.

Surface depletion. While the passivation technique of the invention reduces perimeter currents, it does not eliminate all surface states. It is well known that most III-V semiconductors generally exhibit Fermi level pinning at surfaces. Such Fermi level pinning causes a surface depletion region, which will extend towards the interior of the diode. Assuming a fixed density of surface states, the surface depletion region will be rounded at sharp corners, because each charged surface state must be terminated by a charge in the interior (bulk region) of the diode. Furthermore, note that any rounding (including faceting to non {110} crystal planes, such as {100} and {111} planes) is expected to result in a higher surface state density than the passivated {110} planes, so will enhance the rounding effect of the surface depletion region at corners.

Beveled edges. Many etches of III-V semiconductors are anisotropic, which can allow beveled edges to be produced (see T B Stellwag, M R Melloch, M S Lundstrom, M S Carpenter, and R F Pierret, “Orientation-dependent perimeter recombination in GaAs diodes,” Appl. Phys. Lett., v. 56(17), pp. 1658-1660, 23 Apr. 1990). A positive edge bevel is capable of reducing the electrical field at an edge, thereby preventing premature edge breakdown.

The applicants intend to seek, and ultimately receive, claims to all aspects, features and applications of the current invention, both through the present application and through continuing applications, as permitted by 35 U.S.C. §120, etc. Accordingly, no inference should be drawn that applicants have surrendered, or intend to surrender, any potentially patentable subject matter disclosed in this application, but not presently claimed. In this regard, potential infringers should specifically understand that applicants may have one or more additional applications pending, that such additional applications may contain similar, different, narrower or broader claims, and that one or more of such additional applications may be designated as not for publication prior to grant.

We claim:

1. A method of passivating the {110} surface of a microelectronic device formed from a compound semiconductor by exposing the surface to a HF solution.

2. The method of claim 1 preceded by the step of choosing at least one element of the compound semiconductor from ambng the elements Al, Ga, or In; and at least one element from among the elements As, P, Sb, or N.

3. The method of claim 2 wherein the compound semiconductor is GaAs

4. The method of claim 2 wherein the compound semiconductor is GaInP

5. The method of claim 1 including the step of encapsulating the surface with a dielectric material.

6. The method of claim 5 wherein the dielectric is SiO₂ or Si₃N₄.

7. An electronic device incorporating a HF-passivated {110} surface of a compound semiconductor material.

8. The electronic device of claim 7 wherein said passivated surface is encapsulated with a dielectric material.

9. The electronic device of claim 8 wherein said dielectric material is SiO₂ or Si₃N₄.

10. A metal-insulator-semiconductor (MIS) as said electronic device of claim 8, the insulator including said dielectric material.

11. A metal-insulator-semiconductor field effect transistor (MISFET) including the MIS structure of claim 10.

12. An electronic device incorporating a mesa structure formed from a compound semiconductor, said mesa's side-walls being aligned to the {110} crystal planes and passivated by exposure to a HF solution.

13. The electronic device of claim 12 where the compound semiconductor has at least one n-type region and at least one p-type region.

14. The electronic device of claim 13 formed as a diode.

15. The electronic device of claim 14 formed as an avalanche photodiode.

16. The electronic device of claim 13 formed as a bipolar junction transistor.

17. The electronic device of claim 13 further including at least one i-type region.

18. The electronic device of claim 17 formed as a PIN structure.

19. A photodetector device in accordance with claim 13.

20. A transistor device in accordance with claim 13.
